(19) United States
(12) Patent Application Publication
(10) Pub. No.: US 2019/0051682 A1
(43) Pub. Date: Feb. 14, 2019

(54) SOLID-STATE IMAGING DEVICE AND METHOD OF MANUFACTURING THE SAME

(71) Applicant: TowerJazz Panasonic Semiconductor Co., Ltd., Toyama (JP)

(72) Inventors: Hiroshi TANAKA, Kyoto (JP); Masahiro ODA, Hyogo (JP)

(21) Appl. No.: 16/164,917

(22) Filed: Oct. 19, 2018

Related U.S. Application Data
(63) Continuation of application No. PCT/JP2017/011517, filed on Mar. 22, 2017.

(30) Foreign Application Priority Data
Apr. 21, 2016 (JP) 2016-085061

(51) Int. Cl. H01L 27/146

(52) U.S. Cl. CPC H01L 27/1461; H01L 27/14643; H01L 27/14612; H01L 27/14629; H01L 27/1464; H01L 27/14689; H01L 27/14627; H01L 27/14636; H01L 27/14618

(57) ABSTRACT

The solid-state imaging device according to the present disclosure includes a substrate, a first impurity region of a first conductive type disposed in the substrate, light receiving elements of a second conductive type disposed in the first impurity region, an overflow drain region of the second conductive type disposed below the first impurity region, a second impurity region of the second conductive type configuring, together with the overflow drain region, a drain path for excessive charge from the light receiving elements, and a reflective film.

### CROSS-REFERENCE TO RELATED APPLICATIONS

This is a continuation of International Application No. PCT/JP2017/011517 filed on Mar. 22, 2017, which claims priority to Japanese Patent Application No. 2016-085061 filed on Apr. 21, 2016. The entire disclosures of these applications are incorporated by reference herein.

### BACKGROUND

The present disclosure relates to a solid-state imaging device for use as, for example, a two-dimensional image sensor.

Various types of image sensors that can acquire images of long wavelength light have been developed. Image sensors including silicon substrate in particular have been studied to increase sensitivity of the sensors, since long wavelength light is poorly absorbed by a silicon substrate compared to visible light due to the poor absorption coefficient of silicon. For example, Japanese Unexamined Patent Publication No. 2004-071817 discloses a technique for increasing sensitivity of an image sensor by providing a reflective structure below photodiodes to reflect at least long wavelength light.

This reflective structure is made of an insulating film or a metal film. With this structure, the photodiodes are sandwiched between the reflective structure and an insulating film on an upper surface of the substrate. When the photodiodes are excessively illuminated and generate excessive charge, the excessive charge overflows to adjacent photodiodes. As a result, the image sensor generates signals irrelevant to the subject and the image quality of the resulting image is significantly deteriorated in some cases. This effect is generally called blooming.

Various types of back-illuminated solid-state imaging devices with insulating members sandwiching photodiodes have been suggested. Some of them have a structure for reducing blooming effects. Japanese Unexamined Patent Publication No. 2006-049338 discloses an imaging device including a lateral overflow drain, not a vertical overflow drain because the vertical overflow drain is difficult to fabricate by the typical CMOS process and the difficulty in controlling the fabrication of the vertical overflow drain affects yields of the devices. In this imaging device, excessive charge from the photodiodes is drained to the overflow drain planarly adjacent to the photodiodes.

### SUMMARY

However, using a lateral overflow drain reduces the area for a photodiode in a pixel due to a large footprint of an overflow drain region and an overflow barrier region. To solve the problem above, the semiconductor industry has focused on a solid-state imaging device having a large area of photodiodes with increased sensitivity.

It is an object of the present disclosure to provide a solid-state imaging device that has a sufficient area of photodiodes and can capture images with increased sensitivity without deteriorating image quality.

The solid-state imaging device disclosed in this description includes a substrate having a plurality of pixels arranged two-dimensionally close to an upper surface of the substrate, a first impurity region of a first conductive type disposed in the substrate, light receiving elements of a second conductive type disposed in the first impurity region and provided one by one for the pixels to convert incident light into electric charge, an overflow drain region of the second conductive type disposed below the first impurity region in the substrate, a second impurity region of the second conductive type disposed in the first impurity region and connected to the overflow drain region to configure, together with the overflow drain region, a drain path for excessive charge from the light receiving elements, and a reflective film disposed on or in the substrate and located, relative to the light receiving elements, at a side opposite to a side to which external light enters.

The solid-state imaging device disclosed in this description has a large area of photodiodes and can capture images with increased sensitivity without deteriorating image quality.

### BRIEF DESCRIPTION OF THE DRAWINGS

FIG. 1 is a sectional view of a solid-state imaging device according to a first embodiment of the present disclosure;

FIG. 2 is a plan view of the solid-state imaging device according to the first embodiment seen from above;

FIG. 3 is a graph illustrating a potential level in a plane taken along line A-A′ in the solid-state imaging device illustrated in FIG. 1;

FIG. 4A is a sectional view for describing a method of manufacturing the solid-state imaging device according to the first embodiment;

FIG. 4B is another sectional view for illustrating the method of manufacturing the solid-state imaging device according to the first embodiment;

FIG. 4C is still another sectional view for illustrating the method of manufacturing the solid-state imaging device according to the first embodiment;

FIG. 5 is a sectional view of a solid-state imaging device according to a second embodiment of the present disclosure;

FIG. 6A is a sectional view of a silicon on insulator (SOI) substrate 50 including a gettering layer 41; and

FIG. 6B is a sectional view of a solid-state imaging device according to a third embodiment of the present disclosure.

### DETAILED DESCRIPTION

The following describes embodiments of the present disclosure with reference to the accompanying drawings.

### First Embodiment

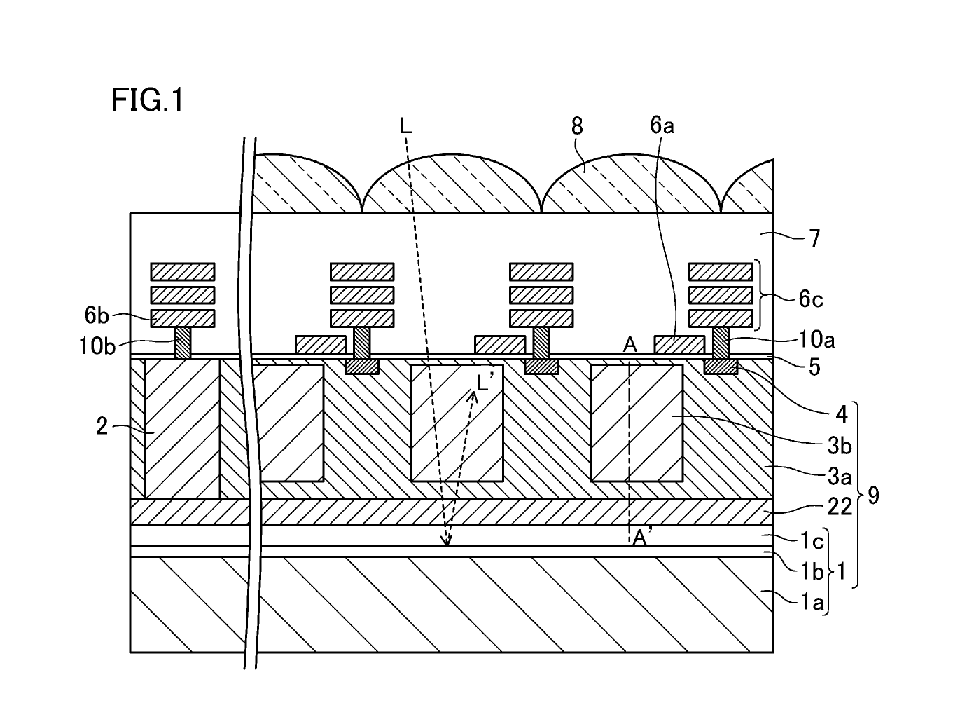

FIG. 1 is a sectional view of a solid-state imaging device according to a first embodiment disclosed in the present description.

As illustrated in FIG. 1, the solid-state imaging device according to the first embodiment includes a substrate 9 having a plurality of pixels arranged two-dimensionally close to an upper surface of the substrate, a first impurity region 3a of a first conductive type disposed in the substrate 9, light receiving elements (photodiodes) 3b of a second conductive type disposed in the first impurity region 3a and provided one by one for the pixels, an overflow drain region 22 of the second conductive type disposed below the first impurity region 3a in the substrate 9, and a second impurity region 2 of the second conductive type connected to the overflow drain region 22 in the first impurity region 3a. In the first embodiment, the first conductive type is p-type and the second conductive type is n-type for example.

The light receiving elements 3b surrounded by the p-type first impurity region 3a receive external incident light L and generate charge. The overflow drain region 22 contains relatively high-concentration n-type impurities. The overflow drain region 22 and the second impurity region 2 configure a drain path for excessive charge from the light-receiving elements 3b.

A reflective film 1b is provided in the substrate 9 and located, relative to the light receiving elements 3b, at a side opposite to a side to which light enters, namely, located below the light receiving elements 3b in the first embodiment. The reflective film 1b reflects incident light L passing through the light receiving elements 3b and causes the light (reflected light L′) to enter the light receiving elements 3b again. The reflective film 1b may be made of, for example, metal, but in one preferred embodiment, the reflective film 1b is made of silicon oxide to prevent contamination around the reflective film 1b.

In the first embodiment, a silicon on insulator (SOI) substrate 1 is used as a substrate including the reflective film 1b. The SOI substrate 1 includes a silicon substrate 1a, the reflective film 1b made of silicon oxide and formed on the silicon substrate 1a, and a silicon layer 1c formed on the reflective film 1b. The SOI substrate 1 can be produced by a known method such as separation by implantation of oxygen (SIMOX) or wafer bonding.

The overflow drain region 22 and the first impurity region 3a on the overflow drain region 22 are formed by epitaxial growth. An insulating film 5 made of silicon oxide is formed on the upper surface of the substrate 9.

Drain regions 4 of n-type (first conductive type) are provided at upper portions of the substrate 9. Gate electrodes 6a are formed, via the insulating film 5, on regions of the substrate 9 each located between a light receiving element 3b and a drain region 4. Portions of the insulating film 5 between the substrate 9 and the gate electrodes 6a function as gate insulating film portions. A drain region 4, a light receiving element 3b, a gate insulating film portion (part of the insulating film 5), and a gate electrode 6a configure a metal oxide semiconductor (MOS) transistor. The thickness of the insulating film 5 may vary between portions below the gate electrodes 6a and the other portions, since the thickness of the insulating film 5 may be reduced in an etching process for forming the gate electrodes 6a.

The solid-state imaging device further includes a planarization layer 7 made of, for example, silicon oxide and formed on the insulating film 5 and the gate electrodes 6a, a plurality of wires 6c disposed in the planarization layer 7 in multi-layered arrangement, contacts 10a each passing through the insulating film 5 to connect the wires 6c with the drain regions 4, and lenses 8 disposed on the planarization layer 7. In the planarization layer 7, a positive voltage application terminal 6b connected to the second impurity region 2 is formed via a contact 10b. During the operation of the solid-state imaging device, positive voltage of approximately 1.0 to 5.0 V is constantly applied to the positive voltage application terminal 6b.

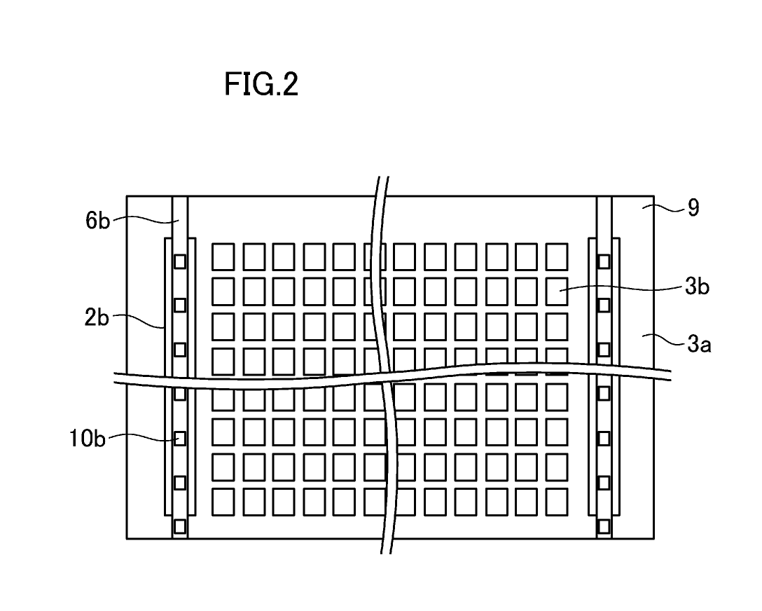

FIG. 2 is a plan view of the solid-state imaging device according to the first embodiment seen from above. In FIG. 2, the lenses 8 and the planarization layer 7 are not illustrated for understanding of the illustration

As illustrated in FIG. 2, for example, the light receiving elements 3b are arranged in a matrix of rows and columns in the substrate 9 and second impurity regions 2 having a strip shape are disposed at left and right end portions of the substrate 9. Positive voltage application terminals 6b having a strip shape are disposed above the second impurity regions 2. The locations of the second impurity regions 2 and the positive voltage application terminals 6b are not limited to end portions, and any given number of the second impurity regions 2 and the positive voltage application terminals 6b may be provided.

The incident light L from the subject enters the pixels such that the incident light L is focused by the lenses 8 to enter the light receiving elements 3b, where signal charge is generated. The generated charge is stored in the light receiving elements 3b. The light passing though the light receiving elements 3b is reflected from the reflective film 1b that is designed to reflect light in consideration of the difference in refractive index between the silicon layer 1c and the reflective film 1b, and the reflected light enters the light receiving elements 3b again. The optical path length of the reflected light L′ is approximately twice the length of the optical path length of the incident light L. Accordingly, the absorption coefficient of the light receiving elements 3b with respect to long wavelength light can approximately be doubled compared to a case of no reflective film 1b.

If the reflective film 1b is made of silicon oxide, the thickness of the reflective film 1b that maximizes the reflectance is calculated from the following interference equation 1.

2·n·t=(N+½)λ Equation 1
t: Thickness of thin film; N: Natural number; n: Refractive index of reflective film

The refractive index n of the silicon oxide film is 1.46, and the thickness t of the reflective film 1b for light having a long wavelength of 850 nm is calculated as 146 nm. In this regard, the reflectance of the reflective film 1b will not be significantly reduced if the thickness of the reflective film 1b is controlled in a range of 150±50 nm, namely, in a range of from 100 nm or greater to 200 nm or smaller.

The overflow drain region 22 of the solid-state imaging device according to the first embodiment, has a thickness of approximately 0.1 to 1.0 μm, and, for example, 0.3 μm.

The impurity concentration of the overflow drain region 22 may be approximately 1×10¹⁶ to 1×10¹⁸ atoms/cm³. In the first embodiment, for example, the impurity concentration of the overflow drain region 22 is 8×10¹⁶ atoms/cm³ and the resistance thereof is 0.1 Ωcm.

Described next is a drain structure for excessive charge. When signal charge is generated within the storage capacity of the light receiving elements 3b, the signal charge is drained through the drain regions 4. Under the control of the gate electrodes 6a, the signal charge is transferred to floating diffusions (not illustrated), converted into voltage through the wires 6c, amplified by amplifier transistors (not illustrated), and read as an image signal. After the signal charge is output as an image signal, the signal charge is drained from the floating diffusions to the drain regions 4.

In a conventional solid-state imaging device, when intense incident light enters the light receiving elements 3b and charge is generated excessively, the excessive charge, which exceeds the amount of charge drained through the drain regions 4, overflows to the adjacent light receiving elements 3b and blooming occurs.

The solid-state imaging device according to the first embodiment includes a large-area vertical overflow drain structure configured by the overflow drain region 22, the second impurity region 2, and the positive voltage application terminal 6b. This structure can easily drain excessive charge without increasing the area of the drain regions 4. Compared to the drain regions 4 that are provided one by one for the light receiving elements 3b, at least one second impurity region 2 and at least one positive voltage application terminal 6b are sufficient to drain charge from a plurality of light receiving elements 3b. This configuration allows the solid-state imaging device according to the first embodiment to reduce blooming without increasing the area of the drain regions 4. In this regard, the solid-state imaging device according to the first embodiment can achieve good image quality if it includes more pixels with higher density.

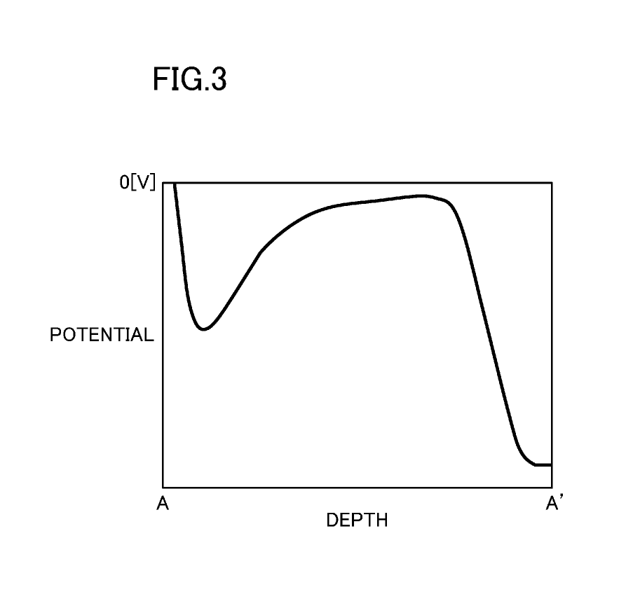

FIG. 3 is a diagram illustrating a potential level in a plane taken along line A-A′ in the solid-state imaging device illustrated in FIG. 1. As illustrated in FIG. 3, the potential of the light receiving element 3b is low, whereas the potential of the first impurity region 3a disposed below the light receiving element 3b is high, which creates what is called a potential barrier. With the potential barrier, charge is stored in the light receiving element 3b, but if charge is excessively generated, the excessive charge overflows to the overflow drain region 22 over the potential barrier. Since the overflow drain region 22 is an n-type region and the positive voltage application terminal 6b applies positive voltage to the overflow drain region 22, the potential of the overflow drain region 22 is lower than that of the light receiving element 3b.

This configuration allows the excessive charge to be promptly drained to the overflow drain region 22 and the second impurity region 2 and to the positive voltage application terminal 6b. This prompt drain process can effectively reduce, for example, charge overflow to the adjacent light receiving elements 3b and blooming. In addition, this configuration can drain dark current. In this regard, the solid-state imaging device according to the first embodiment has good dark current characteristics.

The potential depth of the overflow drain region 22 can be adjusted by controlling the n-type impurity concentration.

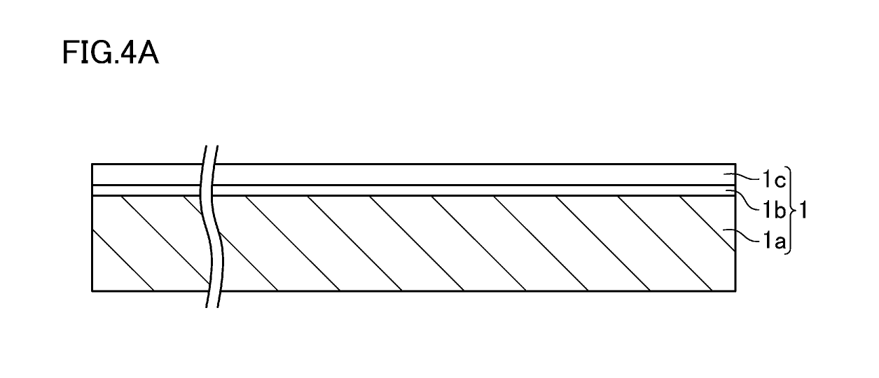

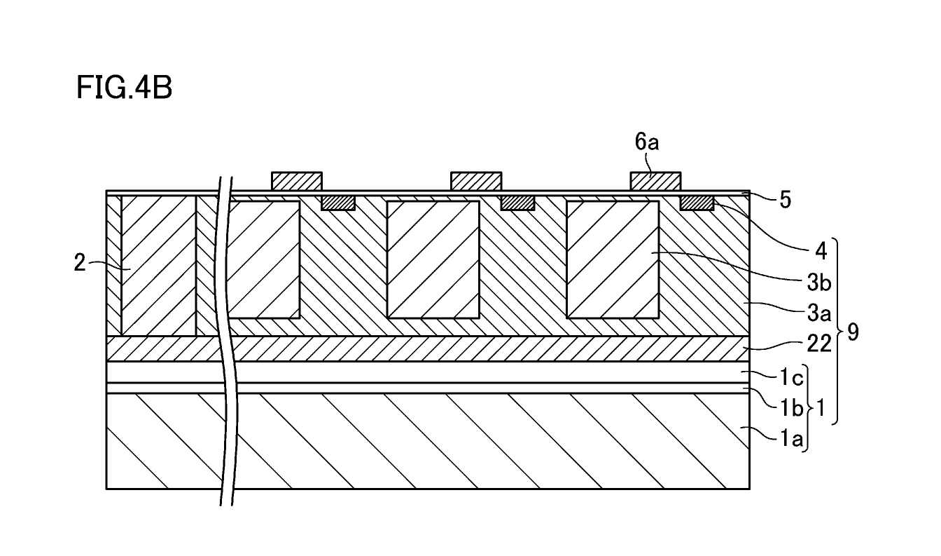

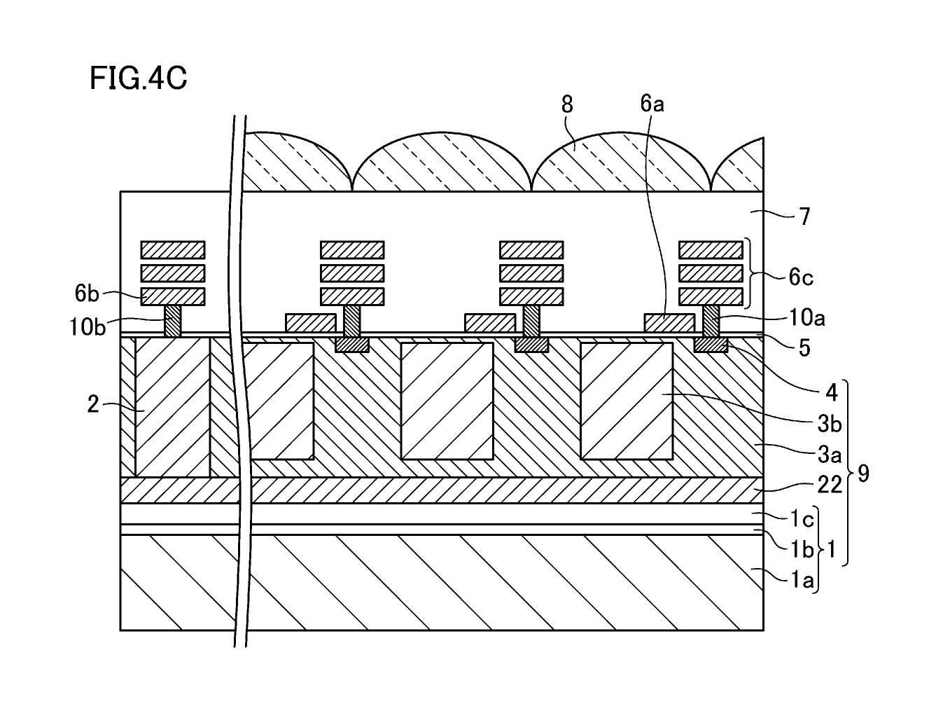

Described next is a method of manufacturing the solid-state imaging device according to the first embodiment. FIGS. 4A to 4C are sectional views for illustrating the method of manufacturing the solid-state imaging device according to the first embodiment.

In the process illustrated in FIG. 4A, an SOI substrate including a silicon substrate 1a, a reflective film 1b, and a silicon layer 1c is prepared. The reflective film 1b is made of silicon oxide and has a thickness of from 100 nm or greater to 200 nm or smaller. The SOI substrate 1 is produced by a known method such as SIMOX or wafer bonding. Commercially available substrates can be used.

In the process illustrated in FIG. 4B, an overflow drain region 22 made of n-type silicon is epitaxially grown on the silicon layer 1c to have a thickness of approximately 300 nm by a known method such as chemical vapor deposition (CVD). The impurity concentration of the overflow drain region 22 is approximately 1×10¹⁶ to 1×10¹⁸ atoms/cm³. The overflow drain region 22 can be formed by ion injection, but using ion injection is unlikely to successfully create a thin region uniformly containing high-concentration impurities in a deep layer of the substrate. To prevent this difficulty, it is preferred that the overflow drain region 22 is created by epitaxial growth, thereby successfully creating a thin overflow drain region 22.

Subsequently, a p-type silicon-based first impurity region 3a is formed by a known method to have a thickness of approximately 6 μm. The impurity concentration of the first impurity region 3a is approximately 1×10¹³ to 1×10¹⁵ atoms/cm³. Phosphorus ion or arsenic ion is injected to certain regions in the first impurity region 3a with a dosage amount of 5×10¹⁰ to 5×10¹³ atoms/cm³ using injection energy of approximately 50 to 5000 keV to create n-type light receiving elements 3b. Phosphorus ion or arsenic ion is injected to a region located at an end portion of the substrate 9 with a dosage amount of 1×10¹² to 1×10¹⁴ atoms/cm³ using injection energy of approximately 10 to 5000 keV to create an n-type second impurity region 2. After that, heat treatment is performed. Either ion injection for creating the light receiving elements 3b or ion injection for creating the second impurity region 2 may be performed earlier.

An insulating film 5 is formed on the substrate 9 by a known method such as thermal oxidation or CVD to have a thickness of approximately 1 to 20 nm, and then gate electrodes 6a are formed. Subsequently, ion injection is performed to create n-type drain regions 4 at regions laterally below the gate electrodes 6a in the substrate 9. The insulating film 5 covers all over the substrate 9.

In the process illustrated in FIG. 4C, a planarization layer 7 with an interlayer insulating film, contacts 10a and 10b, wires 6c, and a positive voltage application terminal 6b are formed on the substrate 9 as appropriate.

Lenses 8 curving upward are formed by a known method on regions of the planarization layer 7 above the corresponding light receiving elements 3b. With these processes above, the solid-state imaging device according to the first embodiment can be manufactured.

### Second Embodiment

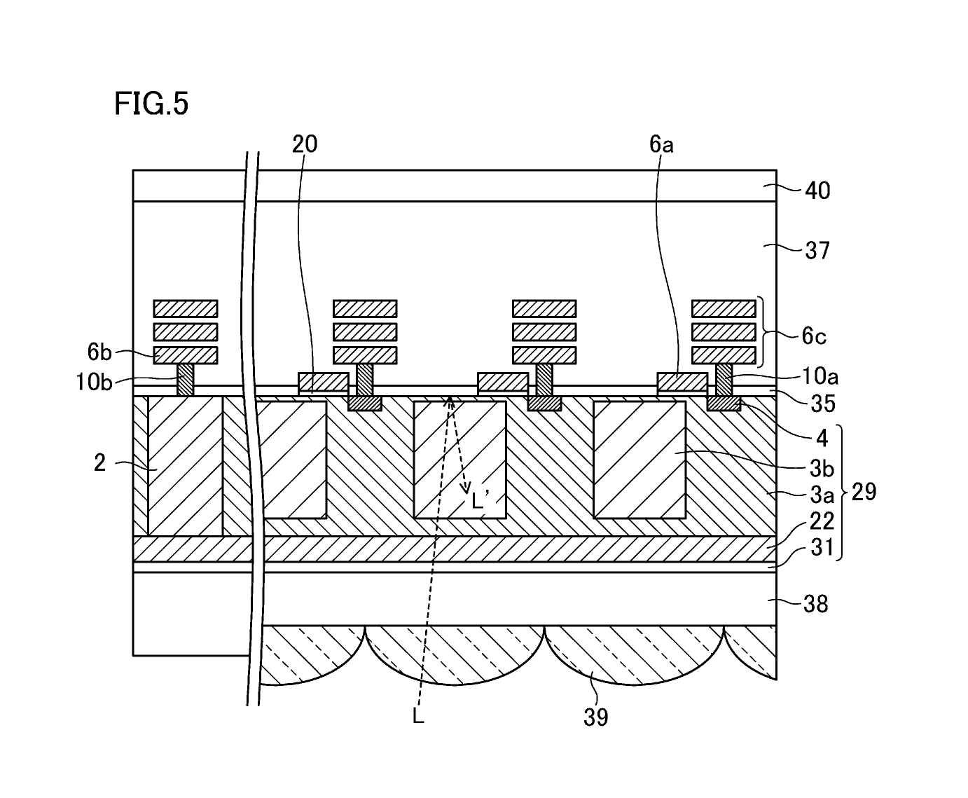

FIG. 5 is a sectional view of a solid-state imaging device according to a second embodiment disclosed in the present description. In FIG. 5, like parts similar to those of the solid-state imaging device according to the first embodiment are similarly numbered.

As illustrated in FIG. 5, the solid-state imaging device according to the second embodiment is designed to receive incident light from a back surface of a substrate 29. The solid-state imaging device according to the second embodiment includes the substrate 29, a first impurity region 3a of a first conductive type disposed in the substrate 29, light receiving elements 3b of a second conductive type disposed in the first impurity region 3a and provided one by one for a plurality of pixels, an overflow drain region 22 of the second conductive type disposed below the first impurity region 3a in the substrate 29, and a second impurity region 2 of the second conductive type connected to the overflow drain region 22 in the first impurity region 3a. The first conductive type is p-type and the second conductive type is n-type, for example. The overflow drain region 22 contains relatively high-concentration n-type impurities. The overflow drain region 22 and the second impurity region 2 configure a drain path for excessive charge from the light-receiving elements 3b.

The substrate 29 includes, for example, an insulating film 31 made of, for example, silicon oxide, and the overflow drain region 22, the first impurity region 3a, and the light receiving elements 3b described above. Although the thickness of the reflective film 1b is described in the first embodiment above, the thickness of the insulating film 31 is not limited to a particular thickness.

The material, thickness, and impurity concentration of the overflow drain region 22 and the first impurity region 3a are identical to those of the solid-state imaging device according to the first embodiment. The impurity concentration of the light receiving elements 3b is identical to that of the solid-state imaging device according to the first embodiment.

The solid-state imaging device according to the second embodiment includes a reflective film 35 made of, for example, silicon oxide and having a thickness of from 100 nm or greater to 200 nm or smaller on at least a region of the substrate 29 above the light receiving elements 3b. A preferred thickness of the reflective film 35 can be calculated by Equation 1 above.

Gate electrodes 6a are provided on the substrate 29 via gate insulating film portions 20 having a thickness of approximately 1 to 20 nm, and n-type drain regions 4 are formed at regions laterally below the corresponding gate electrodes 6a in the substrate 29.

An insulating planarization layer 37 is provided on the reflective film 35 and the gate electrodes 6a. In the planarization layer 37, contacts 10a, wires 6c, and a positive voltage application terminal 6b are provided. A supporting substrate 40 is formed on the planarization layer 37. A transparent, insulating planarization layer 38 is provided on a bottom surface of the substrate 29 (insulating film 31), and lenses 39 are provided on a bottom surface of the planarization layer 38.

The drain regions 4 together with the gate electrodes 6a and some other devices configure MOS transistors. Each drain region 4 is connected to the wires 6c via a contact 10a.

Positive voltage is applied to the positive voltage application terminal 6b during the operation of the solid-state imaging device, and this allows excessive charge to be easily drained from the light receiving elements to the overflow drain region 22 and to the second impurity region 2.

Incident light L from the subject enters the back surface of the substrate 29, and the light is focused by the lenses 39 to enter the light receiving elements 3b. The light receiving elements 3b generate charge by photoelectric conversion and store therein the generated charge. Light passing through the light receiving elements 3b is reflected from the reflective film 35 and enters the light receiving elements 3b again (reflected light L′ in FIG. 5).

Since the reflective film 35 is provided on the top surface of the substrate 29, the solid-state imaging device according to the second embodiment designed to receive incident light from the back surface of the substrate 29 can absorb a larger amount of long wavelength light and convert it into signals.

Since the solid-state imaging device according to the second embodiment includes an overflow drain structure including, for example, the epitaxially grown overflow drain region 22 in the same manner as the first embodiment, the solid-state imaging device can substantially prevent charge overflow to the adjacent light receiving elements 3b and can reduce or prevent blooming.

An example method of manufacturing the solid-state imaging device according to the second embodiment will be described. First, the light receiving elements 3b, the drain regions 4, and the second impurity region 2 are formed by, for example, ion injection in a substrate such as a silicon substrate, and then a thin film, part of which functions as the gate insulating film portions 20, is formed on the upper surface of the silicon substrate by, for example, thermal oxidation. On the gate insulating film portions 20, the gate electrodes 6a having a certain shape are formed. A silicon oxide film is formed on all over the upper surface of the silicon substrate by, for example, CVD, and portions of the silicon oxide film on the gate electrodes 6a are removed. With this process, the reflective film 35 having a thickness of from 100 nm or greater to 200 nm or smaller is formed.

After formation of the reflective film 35, the contacts 10a and 10b, the wires 6c, and the planarization layer 37 are formed by a known method, and then the supporting substrate 40 is bonded to the upper surface of the planarization layer 37.

On the back surface of the silicon substrate, the overflow drain region 22 is epitaxially grown by, for example, CVD, and the insulating film 31 and the planarization layer 38 are formed in this order. Subsequently, the lenses 39 are formed by a known method. With these processes, the solid-state imaging device according to the second embodiment can be manufactured. The order of manufacturing processes of the members and films is not limited to this.

### Third Embodiment

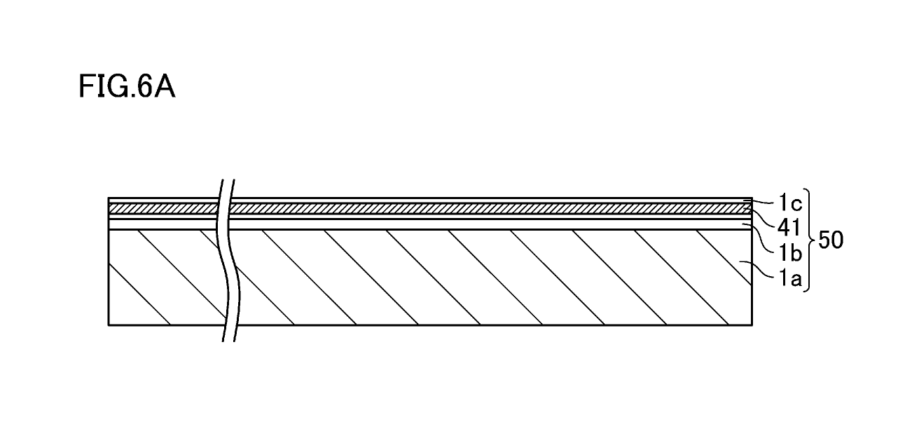

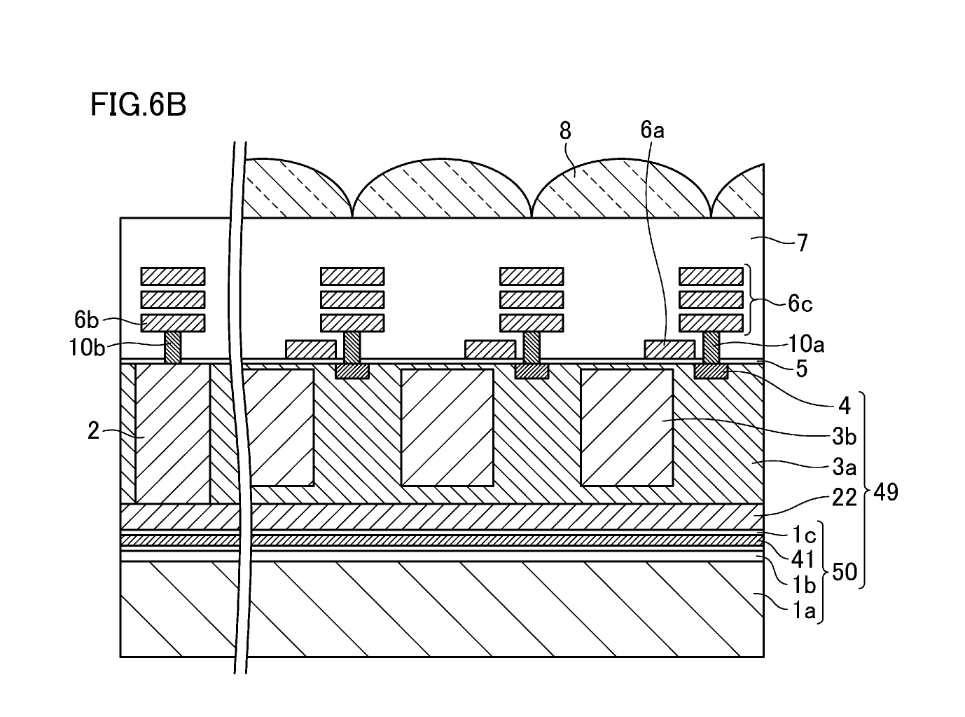

FIG. 6A is a sectional view of an SOI substrate 50 including a gettering layer 41, and FIG. 6B is a sectional view of a solid-state imaging device according to a third embodiment of the present disclosure including the SOI substrate 50.

As illustrated in FIGS. 6A and 6B, the solid-state imaging device according to the third embodiment differs from the solid-state imaging device according to the first embodiment in that the gettering layer 41 is included in the silicon layer 1c of the SOI substrate 50. The other configurations such as the insulating film 5, the gate electrodes 6a, the wires 6c, and the planarization film 7 are identical to those of the solid-state imaging device according to the first embodiment.

As illustrated in FIG. 6B, a substrate 49 includes the SOI substrate 50, a first impurity region 3a, light receiving elements 3b, drain regions 4, and an overflow drain region 22. The configurations of the first impurity region 3a, the light receiving elements 3b, the drain regions 4, and the overflow drain region 22 are identical to those of the solid-state imaging device according to the first embodiment.

The gettering layer 41 contains at least one selected from carbon, nitrogen, and molybdenum, and the material of the gettering layer 41 (e.g., silicon) contains crystal defect. Suppose that the gettering layer 41 contains carbon at a concentration of from 1×10¹⁴ to 5×10¹⁵ atoms/cm³.

In the solid-state imaging device according to the third embodiment, the gettering layer 41 can trap atoms of heavy metal contained in the substrate 49, which can reduce the dark current generated in the light receiving elements 3b. The solid-state imaging device according to the third embodiment can prevent or reduce blooming and can effectively prevent degradation of image quality.

The solid-state imaging devices described above are examples of the embodiments of the present disclosure, and the materials, thickness, and shapes of the constituent members may be modified as appropriate without departing from the scope of the present disclosure. In the first and third embodiments, for example, the SOI substrate may be substituted with other substrates including the reflective film 1b. Although, in the description of the solid-state imaging devices above, the first conductive type is described as p-type and the second conductive type is described as n-type, the first conductive type may be n-type and the second conductive type may be p-type. In this case, negative voltage is applied to the positive voltage application terminal 6b instead of positive voltage.

The constituent members of the first to third embodiments may be combined as appropriate. For example, the solid-state imaging device according to the second embodiment may include the gettering layer 41 in or below the overflow drain region 22 to reduce dark current.

The solid-state imaging device according to the first embodiment may include an insulating film 5 having such a thickness as can function as a reflective film. This configuration can further increase the amount of long wavelength light entering the light receiving elements 3b.

The solid-state imaging device disclosed in the present description can be used for various devices such as digital cameras and mobile phones.

What is claimed is:

1. A solid-state imaging device comprising:
a substrate having a plurality of pixels arranged two-dimensionally close to an upper surface of the substrate;
a first impurity region of a first conductive type disposed in the substrate;
light receiving elements of a second conductive type disposed in the first impurity region, the light receiving elements being provided one by one for the pixels to convert incident light into electric charge;
an overflow drain region of the second conductive type disposed below the first impurity region in the substrate;
a second impurity region of the second conductive type disposed in the first impurity region, the second impurity region being connected to the overflow drain region to configure, together with the overflow drain region, a drain path for excessive charge from the light receiving elements; and
a reflective film disposed on or in the substrate, the reflective film being located, relative to the light receiving elements, at a side opposite to a side to which external light enters.

2. The solid-state imaging device of claim 1, wherein the overflow drain region and the second impurity region create a potential gradient such that charge is drained from the light receiving elements during an operation of the solid-state imaging device.

3. The solid-state imaging device of claim 1, further comprising a drain region of the second conductive type disposed in an upper part of the first impurity region.

4. The solid-state imaging device of claim 1, wherein the reflective film is an insulating film.

5. The solid-state imaging device of claim 4, wherein the substrate includes a silicon on insulator (SOI) substrate including the insulating film.

6. The solid-state imaging device of claim 1, wherein the substrate includes a gettering layer containing at least one selected from carbon, nitrogen, and molybdenum in a region below the overflow drain region.

7. The solid-state imaging device of claim 1, wherein
the reflective film is made of silicon oxide, and
the reflective film has a thickness of from 100 nm or greater to 200 nm or smaller.

8. The solid-state imaging device of claim 1, wherein the overflow drain region is configured by an epitaxially grown layer and has an impurity concentration of from 1×10¹⁶ atoms/cm³ or higher to 1×10¹⁸ atoms/cm³ or lower.

9. A method of manufacturing a solid-state imaging device, the method comprising:
forming an overflow drain region by epitaxial growth on an SOI substrate including a reflective film;
forming a first impurity region of a first conductive type on the overflow drain region; and
forming a second impurity region of a second conductive type and light receiving elements of the second conductive type in the first impurity region, the second impurity region being in contact with the overflow drain region, wherein
the overflow drain region is of the second conductive type.
